(19) United States
(12) Patent Application Publication
(10) Pub. No.: US 2023/0178911 A1
(43) Pub. Date: Jun. 8, 2023

(54) CONNECTOR FOR ELECTRONICALLY CONNECTING PRINTED CIRCUIT BOARDS OF AN ASSEMBLY OF AN ELECTRONIC CONTROL UNIT FOR AN ELECTRIC POWER STEERING SYSTEM

(71) Applicant: Hella GmbH & Co. KGaA, Lippstadt (DE)

(72) Inventor: Kevin Chabillant, Toulouse (FR)

(21) Appl. No.: 18/162,977

(22) Filed: Feb. 1, 2023

Related U.S. Application Data
(63) Continuation of application No. PCT/EP2020/072008, filed on Aug. 5, 2020.

(51) Int. Cl. H01R 12/52; H02K 11/33

(52) U.S. Cl. CPC H01R 12/523; H02K 11/33; H01R 2201/26; H01R 12/58

(57) ABSTRACT

A connector is provided for electronically connecting a first printed circuit board to a second printed circuit board and a third printed circuit board. The connector is configured to form an assembly of an electronic control unit for an electric power steering system. The printed circuit boards are electronically connected with each other by the connector. The connector has a body comprising a base portion and a step portion (20). An assembly of the electronic control unit for the electric power steering system comprising the connector is also provided, along with an electronic control unit itself for the electric power steering system.

### CROSS REFERENCE

This application claims priority to and is a continuation of PCT Application No. PCT/EP2020/072008, filed Aug. 5, 2020, the entirety of which is hereby incorporated by reference.

### FIELD OF THE INVENTION

The invention is directed at a connector for electronically connecting printed circuit boards to an assembly of an electronic control unit for an electric power steering system, the assembly of the electronic control unit for the electric power steering system comprising the connector and the electronic control unit for the electric power steering system comprising the assembly.

### BACKGROUND OF THE INVENTION

In an electric power steering system, an electronic control unit can be connected with an electric motor for supplying power to the electric motor from a power source such as a battery. The electric power steering system can assist in a handling operation, typically a steering, of a transportation equipment, either by a driver or by a machine in an autonomous vehicle. The transportation equipment can be an automobile.

The electric power steering system may further comprise a torque sensor, a steering shaft, a handle, typically a steering wheel, and the power source. In the following, a typical arrangement and operation of the electric power steering apparatus in an automobile will be described.

The torque sensor may be mounted on the steering shaft. Upon rotating the steering shaft by operating the handle, the torque sensor detects a torque being applied to the steering shaft by the operation of the handle. Upon detection of the torque by means of the torque sensor, a torque signal is output from the torque sensor to the electronic control unit. The electronic control unit then drives the electric motor based at least on the torque signal. Optionally, the control device may include further data such as vehicle speed in addition to the torque signal for controlling the driving of the electric motor.

The electronic control unit drives the electric motor by supplying a driving current from the power source, such as the battery of the automobile, to the electric motor. A driving force generated from the electric motor is then transmitted to the wheels directly or via a gearbox depending on the configuration in the automobile. As a result, the electric power steering apparatus changes a steering angle of the wheels by amplifying the torque of the steering shaft by means of the electric motor. This enables the driver to operate the handle with less force.

The electronic control unit comprises a power board electrically connected with the electric motor. The power to the electric motor is transmitted via this power board. A logic board is connected to this power board for controlling the transmission of power to the electric motor. The power board and the logic board are provided as printed circuit boards. The power board generates heat during operation of the electronic control unit. To prevent overheating and damage of the electronic control unit, a heat sink may be provided inside of the electronic control unit and arranged in thermal contact with a housing of the electric power steering system or electric motor.

In particular when there are more than two printed circuit boards, e.g. three printed circuit boards, such as two for providing the power and one for providing the logic or control operation, for example, it may be difficult to get a compact assembly having the printed circuit boards electronically connected to each other while providing the assembly with enough space for the printed circuit boards, electronic components thereof and a heat sink, for example.

### BRIEF SUMMARY OF THE INVENTION

Therefore, it is an objective of the present invention to provide a connector for electronically connecting printed circuit boards to an assembly of an electronic control unit for an electric power steering system, enabling a corresponding assembly to be more compact and have more space for respective components of the assembly.

This objective is solved by a connector for electronically connecting a first printed circuit board to a second printed circuit board and a third printed circuit board according, an assembly of an electronic control unit for an electric power steering system comprising the connector, and an electronic control unit for an electric power steering system comprising the connector. The features and details described in connection with connector of the invention apply in connection with the assembly and the electronic control unit as well as the other way around, so that regarding the disclosure of the individual aspects of the invention, it is or can be referred to one another.

According to a first aspect of the invention, the above objective is solved by a connector for electronically connecting a first printed circuit board to a second printed circuit board and a third printed circuit board. The connector is configured to form an assembly of an electronic control unit for an electric power steering system, when the printed circuit boards are electronically connected with each other by means of the connector. The connector has a body comprising a base portion having a first connection mechanism and a second connection mechanism, wherein the first connection mechanism and the second connection mechanism are electronically connected to each other, the first connection mechanism extends from a first side of the base portion, the second connection mechanism extends from a second side of the base portion, the first connection mechanism is configured for electronically connecting to the first printed circuit board and the first connection mechanism is configured for electronically connecting to the third printed circuit board. The body further comprises a step portion projecting from the base portion and having a third connection mechanism and a fourth connection mechanism, wherein the third connection mechanism and the fourth connection mechanism are electronically connected with each other, the third connection mechanism extends from the step portion, the fourth connection mechanism extends from the step portion, the third connection mechanism is configured for electronically connecting the third connection mechanism with the first printed circuit board and the fourth connection mechanism is configured for electronically connecting with the second printed circuit board.

Accordingly, the invention provides for the compact yet component spacious assembly by providing a connector having a base portion with an electronical connection mechanism and a step portion projecting therefrom having an electronical connection mechanism. While the first connection mechanism of the base portion electronically connects to the first printed circuit board and the third connection mechanism of the step portion connects to the first printed circuit board as well, the second connection mechanism of the base portion and the fourth connection mechanism of the step portion connect to different printed circuit boards, namely the second printed circuit board and the third printed circuit board. By means of providing the single connector formed as depicted above, in particular with the step portion projecting from the base portion, as further explained below, it is possible to electronically connect the three printed circuit boards to the compact yet component spacious assembly.

The base portion and the step portion may be made from one piece. The base portion and the step portion may be molded over the connection mechanism such that these are embedded into the base portion and step portion of the connector. The base portion and the step portion may be made from a plastic or any other suitable material for embedding the connection mechanism therein.

The step portion may have a smaller height than the base portion. Since the step portion projects from the base portion, it thereby provides the fourth connection mechanism at a smaller height along the base portion, measured from the side at which the first connection mechanism extends from the base portion compared to the second connection mechanism at the base portion. Thereby, it is possible to connect the second printed circuit board and the third printed circuit board at respectively different heights or planes with respect to a height of the base portion or an overall height of the connector, which may be the same as the one of the base portions, i.e. determined by the base portion. The height of the base portion or connector may be measured along a height axis. The height axis may correspond to the extension of the connection mechanism from the base portion or step portion or, in other words, it may be measured in a direction transverse, in particular perpendicular, to a longitudinal extension of the base portion or connector. Accordingly, the step portion may be seen as a step of the connector extending from the base portion.

Further, the first side may be opposite to the second side. Accordingly, the first connection mechanism and the second connection mechanism extend in opposite directions of a height axis of the base portion. Thereby the first printed circuit board and the third printed circuit board may be connected opposite of one another, in particular parallel to one another.

Moreover, the third connection mechanism may extend from the first side of the base portion. The first side may be a common side of the base portion and the step portion. Thereby, the first printed circuit board may be connected with the first connection mechanism and the third connection mechanism at the common side of the connector despite being provided on different portions, namely the base portion and the step portion, of the connector. Accordingly, the first connection mechanism and the third connection mechanism can be electronically connected with the first printed circuit board next to each other and on the same plane or height of the connector.

Also, the fourth connection mechanism may extend from a third side of the step portion, wherein the third side is opposite to the first side. That third side may terminate before the second side along the height of the base portion or connector. Thereby, the fourth connection mechanism and the second connection mechanism become arranged at different heights of the base portion or connector, enabling them to arrange the respective printed circuit boards effectively with regards to space in the assembly.

Further on, the step portion may project from the base portion into a direction transverse, in particular perpendicular or substantially perpendicular, of the extension of the first connection mechanism, second connection mechanism, third connection mechanism and/or fourth connection mechanism. Substantially perpendicular includes a deviation from a mathematical perpendicularity due to technical restrictions, such as caused by dimensional tolerance.

Moreover, the first connection mechanism, the second connection mechanism, the third connection mechanism and/or the fourth connection mechanism may be pins, in particular press-fit pins. The connection mechanisms, in particular the pins, may be made from metal, for example from copper, to provide proper electrical conductivity characteristics. The pins may be easily fitted into corresponding connection openings, such as holes, for accommodating the pins inside of the printed circuit boards. The press-fit pins are a particularly simple solution for insertion into the corresponding connection openings of the printed circuit boards.

Further, the connector may comprise a positioning mechanism, in particular elastic pins, for fixing the connector to at least one of the first printed circuit board, the second printed circuit board and the third printed circuit board and/or a heat sink of the electronic control unit. The connection mechanisms alone may not be sufficient to provide positioning of the connector within the assembly, i.e. at the printed circuit boards, for the purpose of which the positioning mechanism may be fitted into corresponding positioning openings of at least one of the printed circuit boards and/or of a heat sink of the electronic control unit. The positioning mechanism may be referred to as fixing means as well, as they provide a fixture of the connector relative to the at least one printed circuit board and/or the heat sink. The positioning mechanism may be made from one piece together with the base portion and step portion of the connector. The positioning mechanism may in particular extend from the base portion and/step portion along the height axis of the base portion or connector. The position means may comprise a positioning head at its end. This head may be heated, in particular when it is made from a plastic, to become flexible and then inserted into the corresponding positioning opening.

Also, the connector may have a circular longitudinal extension and/or the first connection mechanism is arranged along a first circular path, the second connection mechanism is arranged along a second circular path, the third connection mechanism is arranged along a third circular path and/or the fourth connection mechanism is arranged along a fourth circular path. In other words, the longitudinal extension of the connector may follow a circular path. The respective connection mechanisms may follow or be aligned a respective circular path along that longitudinal extension. This arrangement is preferable as it may be easily positioned at the periphery of printed circuit boards and thereby save space on the printed circuit boards.

According to a second aspect of the invention, the objective raised in the introductory part of this description is solved by an assembly of an electronic control unit for an electric power steering system comprising the connector according to the first aspect of the invention, whereby the connector is electronically connecting the first printed circuit board to the second printed circuit board by means of the first connection mechanism and the second connection mechanism and the connector is electronically connecting the first printed circuit board to the third printed circuit board by means of the third connection mechanism and the fourth connection mechanism.

Thereby, the advantages associated with the connector according to the first aspect of the invention are realized in the electronic control unit for the electric power steering system. Therein, the electric power steering system may in particular be the one of an automobile.

The assembly and/or the electronic control unit may further comprise a heat sink and a housing. The housing may enclose the printed circuit boards electronically connected with each other by means of the connector. The heat sink may be positioned in between a space between two printed circuit boards, in particular the power boards, such that it may dissipate the heat generated by the power boards. The heat sink may be thermally connected with the housing such that the heat is dissipated via the housing.

The connector may be provided on a periphery of the printed circuit boards. Thereby, space is saved on the printed circuit boards for providing thereon electronic components and possibly arranging a heat sink in between two of the printed circuit boards.

Further, the first printed circuit board may be a logic board and the second printed circuit board and the third printed circuit board may be power boards. In such a configuration with two power boards, the electric motor may be electrically connected by means of a first electric motor connector to the first power board and by means of a second electric motor connector to the second power board. Each of the power boards may supply a three-phase electric current. The electric motor may thus be designed as a six-phase electric motor. Thereby, the electric motor can be separately driven by the driving current supplied separately by any one or both of the two power boards. This provides for a redundant and failure unsusceptible design of the electronic control unit and the electric power steering system.

Further, the electronic control unit may comprise the electric motor as previously explained. The electric motor may be electronically connected to the power boards of the printed circuit boards by means of the electric motor connectors for each of the power boards.

Also, the printed circuit boards may have a circular or substantially circular shape. A substantially circular shape in this sense is a shape having at least more than half of its circumference being circular. The circular shape of the printed circuit boards has been found to be advantageous with respect to a compact assembly.

Further, the second printed circuit board may be smaller in diameter than the third printed circuit board. In addition, the second circuit board may be smaller in diameter than the first printed circuit board. The first printed circuit board and the third printed circuit board may be of equal or substantially equal size, which includes dimensional tolerances. This is a consequence of a design with a step portion extending into the middle of the second printed circuit board of the assembly. Although some space is lost on the second printed circuit board compared to the first printed circuit board and the third printed circuit board, the overall design of the assembly becomes more compact and the space for the second printed circuit board becomes larger compared to other arrangements.

According to a third aspect of the invention, the objective raised in the introductory part of this description is solved by an electronic control unit for an electric power steering system, in particular of an automobile, comprising the assembly according to the second aspect of the invention.

Accordingly, the electronic control unit, and also the electric power steering system, may benefit from the advantageous connector of the first aspect of the invention as explained above.

The electric power steering system may further comprise a torque sensor, a steering shaft, a handle, in particular a steering wheel, and a power source. The electric power steering system may further have the arrangement and be arranged for operation of an automobile as described in the introductory part of this description.

Further advantages, features and details of the invention unfold from the following description, in which by reference to drawings of the following figures, an embodiment of the present invention is described in detail. Thereby, the features from the claims as well as the features mentioned in the description can be essential for the invention as taken alone or in an arbitrary combination.

### BRIEF DESCRIPTION OF THE DRAWINGS

Reference is now made more particularly to the drawings, which illustrate the best presently known mode of carrying out the invention and wherein similar reference characters indicate the same parts throughout the views.

FIG. 1 is a side perspective sectional view on an assembly according to an embodiment of the invention.

FIG. 2 is a side perspective view on the connector according to an embodiment of the invention as contained in the assembly of FIG. 1.

FIG. 3 is a sectional view on the connector of FIG. 2.

FIG. 4 is a sectional schematic view on the assembly of FIG. 1.

FIG. 5 is a front perspective view on an automobile equipped with an electronic control unit according to an embodiment of the invention.

### DETAILED DESCRIPTION OF THE DRAWINGS

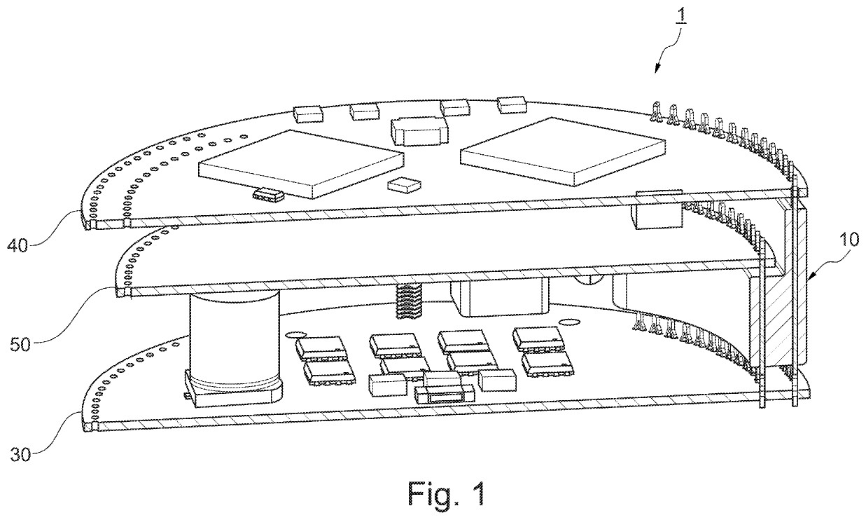

FIG. 1 shows an assembly 1 according to an embodiment of the invention. The assembly 1 comprises three printed circuit boards 30, 40, 50. The first printed circuit board 30 is a logic board of an electronic control unit 102 (see FIG. 5), the second printed circuit board 40 is a first power board of the electronic control unit 102 and the third printed circuit board 50 is a second power board of the electronic control unit 102.

In the assembly 1, the first printed circuit board 30 designed as the logic board is electronically connected with the second printed circuit board 40 and the third printed circuit board 50 designed as power boards via a connector 10. By means of the connector 10, the three printed circuit boards 30, 40, 50 are arranged parallel to one another in the assembly 1.

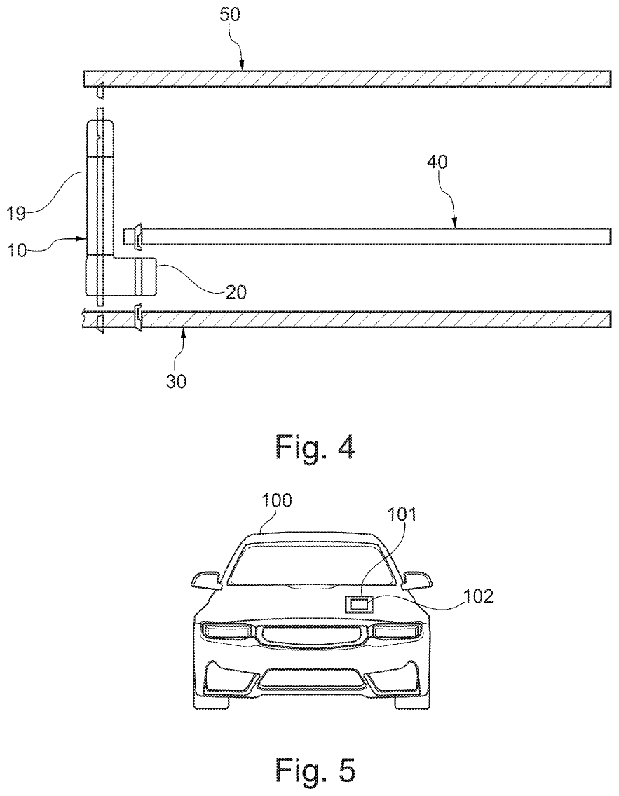

As can be seen particularly well from FIG. 4, the connector 10 comprises a base portion 19 and a step portion 20. The base portion 19 has a height extension along a height axis (not shown) and the base portion 19 determines the overall height of the connector 10. The step portion 20 extends in length along a direction perpendicular to the direction of height extension or the height axis of the base portion 19. The step portion 20 comprises a relatively small height compared to the height of the base portion 19. Accordingly, there is a large space in between the second printed circuit board 40 and the third printed circuit board 50. A heat sink (not shown) for dissipating heat from the printed circuit boards 40, 50 may be provided therein because the printed circuit boards 40, 50 are designed as power boards and thereby generate a large amount of heat during their operation controlled by the first printed circuit board 30 designed as the logic board.

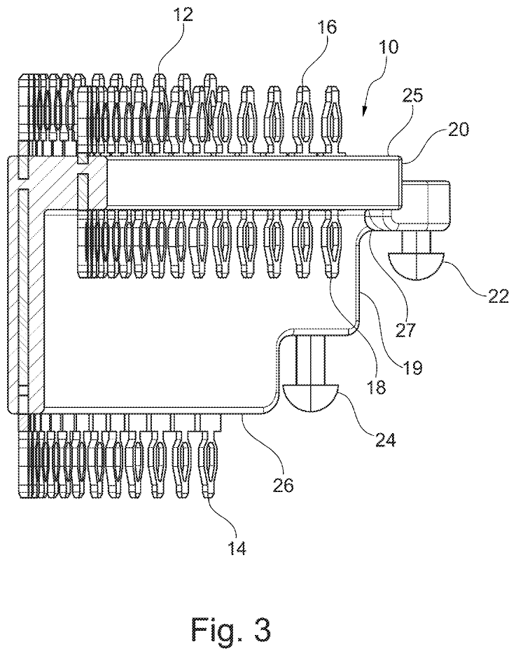

The design of the connector 10 will be further explained with reference to FIGS. 3 and 4 showing the connector 10 of the assembly 1 of FIGS. 1 and 4 in more detail.

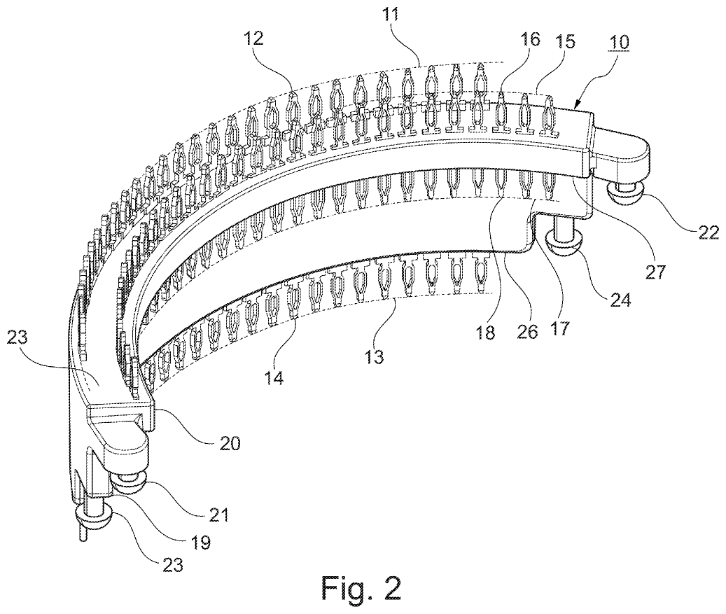

The connector 10 has a circular longitudinal extension or, in other words, a rounded shape along its length, as can be taken particularly well from FIG. 2. Correspondingly, the printed circuit boards 30, 40, 50 are designed with a circular shape. Thereby, the connector 10 may be particularly well positioned at the periphery of the printed circuit boards 30, 40, 50, as shown in FIGS. 1 and 4. This saves space on the printed circuit boards 30, 40, 50.

The connector 10 further comprises one or multiple first connection mechanisms 12 electronically connected to the first printed circuit board 30, which can be taken from FIG. 1. These one or multiple first connection mechanisms 12 are disposed at a first side 25 on the connector 10 or the base portion 19 thereof. Opposite of the first side 25 on a second side 26, there are one or multiple second connection mechanisms 14 disposed on the connector 10. As can be taken from FIG. 1, these one or multiple connection mechanisms 14 electronically connect to the third printed circuit board 50. Further, one or multiple third connection mechanisms 16 are disposed again on the first side 25 of the connector 10. Here, the first side 25 is a common side of the base portion 19 and the step portion 20. The one or multiple third connection mechanisms 16 again connect to the first printed circuit board 30. Finally, there are one or multiple fourth connection mechanisms 18 disposed on a third side 27 of the step portion 20 opposite of the first side 25. The one or multiple fourth connection mechanisms 18 electronically connect to the second printed circuit board 40. Each of the one or multiple first connection mechanisms 12 is connected within the base portion 19 to each of the one or multiple second connection mechanisms 14, and each of the one or multiple third connection mechanisms 16 is connected within the step portion 20 to each of the one or multiple fourth connection mechanisms 18. By the described scheme of connection mechanisms 12, 14, 16, 18, the first printed circuit board 30 is operatively connected to both printed circuit boards 40, 50 for control thereof.

Each of the one or multiple first connection mechanisms 12, second connection mechanisms 14, third connection mechanisms 16 and fourth connection mechanisms 18 are provided along respective rows, in particular along the circular longitudinal extension of the connector 10. The respective rows are imaginary circular paths 11, 13, 15, 17 drawn along each of the respective multiple first connection mechanisms 12, second connection mechanisms 14, third connection mechanisms 16 and fourth connection mechanisms 18. Therein, the first circular path 11 is coaxial to the third circular path 15 and the fourth circular path 17. The second circular path 13 is parallel to the first circular path 11.

Each one of the multiple connection mechanisms 12, 14, 16, 18 is designed as a press-fit pin for insertion into corresponding connection openings (not referenced but depicted in FIG. 1) within the printed circuit boards 30, 40, 50, whereby the electronical connection between the respective parts is provided.

As can be further taken from FIGS. 2 and 3, the connector 10 comprises positioning mechanisms 21, 22, 23, 24 for positioning the connector 10 in corresponding positioning openings (not shown) of the second printed circuit board 40 and the heat sink (not shown). Therein, the first and second positioning mechanisms 21, 22 are provided for positioning at the second printed circuit board 40 and the third and fourth positioning mechanisms 23, 24 are provided for positioning at the heat sink.

The positioning mechanisms 21, 22, 23, 24 are provided with heads at their ends and are integrally formed with the base portion 19 and the step portion 20 from plastic. They are heated prior to inserting them into the corresponding positioning openings, whereby they can be flexibly arranged within them. Of course, the positioning of the connector 10 within the assembly 1 may be achieved in alternative ways as well and the described one is only exemplary.

FIG. 5 shows an automobile 100 as one exemplary transportation equipment, which may be equipped with the electronic control unit 102. As can be taken from this schematic representation of the electric power steering system 101, the electronic control unit 102 is included in the electric power steering system 101, which is installed in the automobile 100.

### REFERENCE SIGN LIST

1 Assembly
10 Connector
11 first circular path
12 first connection mechanism
13 second circular path
14 second connection mechanism
15 third circular path
16 third connection mechanism
17 fourth circular path
18 fourth connection mechanism
19 base portion
20 step portion
21 first positioning mechanism
22 second positioning mechanism
23 third positioning mechanism
24 fourth positioning mechanism
25 first side
26 second side
27 third side
30 first printed circuit board
40 second printed circuit board
50 third printed circuit board
100 automobile
101 electric power steering system
102 electronic control unit

1. A connector for electronically connecting a first printed circuit board to a second printed circuit board and a third printed circuit board, wherein the connector forms an assembly of an electronic control unit for an electric power steering system when the printed circuit boards are electronically connected with each other by the connector, the connector comprising:
a body including:
a base portion having a first connection mechanism and a second connection mechanism, wherein the first connection mechanism and the second connection mechanism are electronically connected to each other, wherein the first connection mechanism extends from a first side of the base portion, the second connection mechanism extends from a second side of the base portion, the first connection mechanism being configured for electronically connecting to the first printed circuit board and the second connection mechanism being configured for electronically connecting to the third printed circuit board, and
a step portion projecting from the base portion and having a third connection mechanism and a fourth connection mechanism, wherein the third connection mechanism and the fourth connection mechanism are electronically connected with each other, wherein the third connection mechanism extends from the step portion, the fourth connection mechanism extends from the step portion (20), wherein the third connection mechanism is configured for electronically connecting the third connection mechanism to the first printed circuit board and the fourth connection mechanism is configured for electronically connecting to the second printed circuit board.

2. The connector according to claim 1, wherein the step portion has a smaller height than the base portion.

3. The connector according to claim 1, wherein the first side is opposite to the second side.

4. The connector according to claim 3, wherein the third connection mechanism extends from the first side of the base portion and the first side is a common side of the base portion and the step portion.

5. The connector according to claim 3, wherein the fourth connection mechanism extends from a third side of the step portion, wherein the third side is opposite to the first side.

6. The connector according to claim 1, wherein the step portion projects from the base portion into a direction transverse of the extension of the first connection mechanism, the second connection mechanism, the third connection mechanism and/or the fourth connection mechanism.

7. The connector according to claim 1, wherein the first connection mechanism, the second connection mechanism, the third connection mechanism and/or the fourth connection mechanism are pins.

8. The connector according to claim 1, further including a positioning mechanism for fixing the connector to at least one of the first printed circuit board, the second printed circuit board, and the third printed circuit board, and/or a heat sink of the electronic control unit.

9. The connector according to claim 1, wherein the connector has a circular longitudinal extension and/or the first connection mechanism is arranged along a first circular path, the second connection mechanism is arranged along a second circular path, the third connection mechanism is arranged along a third circular path and/or the fourth connection mechanism is arranged along a fourth circular path.

10. An assembly of an electronic control unit for an electric power steering system comprising:
the connector according to claim 1, wherein the connector electronically connects the first printed circuit board to the second printed circuit board via the first connection mechanism and the second connection mechanism, and the connector electronically connects the first printed circuit board to the third printed circuit board via the third connection mechanism and the fourth connection mechanism.

11. The assembly according to claim 10, wherein the connector is provided on a periphery of the printed circuit boards.

12. The assembly according to claim 10, wherein the first printed circuit board is a logic board and the second printed circuit board and the third printed circuit board are power boards.

13. The assembly according to claim 10, wherein the printed circuit boards have a circular or substantially circular shape.

14. The assembly according to claim 13, wherein the second printed circuit board is smaller in diameter than the third printed circuit board.

15. An electronic control unit for an electric power steering system comprising the assembly according to claim 10.
